(19) United States
(12) Patent Application Publication
(10) Pub. No.: US 2017/0066088 A1
(43) Pub. Date: Mar. 9, 2017

(54) BALL GRID ARRAY (BGA) APPARATUS AND METHODS

(71) Applicant: Intel Corporation, Santa Clara, CA (US)

(72) Inventors: Mohit Sood, Chandler, AZ (US); Boxi Liu, Chandler, AZ (US); Wei Tan, Chandler, AZ (US); Huili Xu, Chandler, AZ (US); Kabir J. Mirpuri, Scottsdale, AZ (US)

(21) Appl. No.: 14/846,489

(22) Filed: Sep. 4, 2015

(51) Int. Cl. B23K 35/26; B23K 35/02; H01L 23/00; H05K 3/36; H01L 21/48; H05K 1/18; H05K 1/14; H05K 3/34; B23K 1/00; H01L 23/498

(52) U.S. Cl. CPC B23K 35/262; B23K 1/0016; B23K 35/0244; H01L 24/17; H01L 23/49816; H01L 23/49833; H01L 24/81; H01L 21/4853; H05K 1/181; H05K 1/144; H05K 3/3436; H05K 3/363; H01L 2924/15311; H01L 2924/15321; H01L 2924/15331; H01L 2224/13014; H01L 2224/13016; H01L 2224/13111; H01L 2224/13113; H01L 2224/16225; H01L 2224/16502; H01L 2224/812; H01L 2224/81801; H01L 2924/20104; H01L 2924/20105; H05K 2201/042; H05K 2201/10234; H05K 2201/10378; H05K 2203/041

(57) ABSTRACT

Embodiments herein may relate to an apparatus with a ball grid array (BGA) package that includes a plurality of solder balls of an off-eutectic material. In embodiments, the respective solder balls of the plurality of solder balls may form solder joints between a substrate of the BGA and a second substrate. In some embodiments the joints may be less than approximately 0.6 micrometers from one another. Other embodiments may be described and/or claimed.

### TECHNICAL FIELD

The present disclosure relates generally to the field of solder joints, and more specifically to solder joints that include an off-eutectic material.

### BACKGROUND

Surface mount of ball grid array (BGA) packages may face a high risk for bridging due to package dynamic warpage during reflow process. For example, the reflow process may include the application of heat to the package, which in turn may cause the package to warp in some manner that different solder balls of the BGA package may flow into one another during the reflow process, resulting in bridging between two solder joints. This warpage and bridging phenomenon has been found to be even more severe for coreless client packages and package on interposer (PoINT) server products for which the warpage may exceed permissible specifications such as those set by the Joint Electron Device Engineering Council (JEDEC).

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a simplified view of a BGA, in accordance with various embodiments.

FIG. 2 is an example phase diagram of an off-eutectic solder material, in accordance with various embodiments.

FIG. 3 is a side, cross-sectional view of a package that includes a BGA and a substrate, in accordance with various embodiments.

FIG. 4 is a side view of an integrated circuit (IC) package that may include the package of FIG. 3, in accordance with various embodiments.

FIG. 5 is an example diagram of shear modulus versus temperature for a eutectic and off-eutectic solder material, in accordance with various embodiments.

FIG. 6 is an example diagram of viscosity versus temperature for a eutectic and off-eutectic solder material, in accordance with various embodiments.

FIG. 7 is an example process for making the package of FIG. 2, in accordance with various embodiments.

FIG. 8 is an example computing device that may include the package of FIG. 2, in accordance with various embodiments.

### DETAILED DESCRIPTION

Embodiments herein may relate to increasing resistance to solder collapse driven by package dynamic warpage during a reflow process. This resistance may be achieved by using an off-eutectic solder metallurgy with sufficiently wide solidus and liquidus temperatures, and making solder joints at temperatures between the solidus and liquidus temperatures of the solder.

As used herein “off-eutectic” may indicate that the solder material has a temperature where it becomes completely molten (i.e., a “liquidus” temperature) when heated, and that temperature may be different than the temperature at which it becomes completely solid (i.e., a “solidus” temperature) when cooled. Such a solder may also be referred to as “two-phase.” In embodiments, the solidus temperature may be lower than the liquidus temperature as described in further detail below. In these embodiments, if the off-eutectic solder is heated to a temperature between the solidus temperature and the liquidus temperature, the solder may be in a semi-solid/semi-liquid state. Reflowing the solder in the temperature range between the solidus and liquidus temperature may increase the solder shear modulus and viscosity, and make the resultant solder joint stiffer.

Generally, legacy packages may use different processes to contain solder bump bridging (SBB) during surface mount processes. These processes may be generally bucketed under process, board design, and package architecture. Process based solutions may be limited to optimization of paste print volumes and process parameters such as stencil separation speed, etc. However, paste volume in process-based solutions may not be reduced beyond a certain point without increasing risk for non-contact opens, and so such a process-based solution may not be adequate for certain applications.

Similarly, board design solutions such as usage of metal defined (MD) pads may be used to reduce joint widths, and thus reduce SBB. However, low trench width and restrictions on MD pad locations on the board may limit the effectiveness of MD pads in some situations.

Similarly, modification of package architecture to control package dynamic warpage may include options such as mold over packages, stiffener over packages, die thinning, package flattening, and copper density distribution within substrates. However, in some cases such solutions may be relatively complicated and/or cost intensive.

By contrast, embodiments herein may improve susceptibility to SBB without significantly increasing manufacturing costs. Specifically, embodiments herein may have relatively simplified implementation without appreciable increase in associated manufacturing operations. Furthermore, the process may be tailored around different solder metallurgies, such as high temperature tin/gold/copper (SAC) metallurgies or bismuth/indium doped low temperature metallurgies.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other.

In various embodiments, the phrase “a first layer formed on a second layer” may mean that the first layer is formed over the second layer, and at least a part of the first layer may be in direct contact (e.g., direct physical and/or electrical contact) or indirect contact (e.g., having one or more other layers between the first layer and the second layer) with at least a part of the second layer.

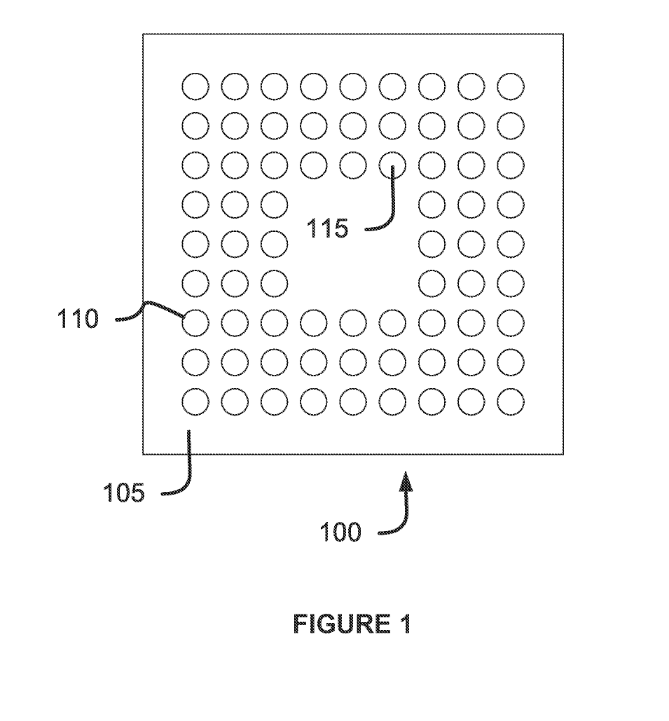

FIG. 1 depicts an example ball grid array (BGA) 100. The BGA 100 may include a substrate 105. The substrate 105 may include inner solder balls 115 and outer solder balls 110 (collectively referred to herein as solder balls 110 and 115.) In embodiments herein, the solder balls 110 and 115 may be made of an off-eutectic material. In embodiments herein, a tin-bismuth (Sn—Bi) material may be discussed, but in other embodiments the off-eutectic material may be or include a high temperature tin/gold/copper (SAC) material, a low temperature solder material doped with bismuth, indium, gallium, zinc, and/or some other material. In some embodiments, the substrate 105 may include or be formed of some thermally and/or electrically neutral material such as fiberglass, epoxy, silicon, or some other material. In some embodiments, the solder balls 110 and 115 may also be referred to as solder “bumps.” Generally, as used herein, a solder ball or solder bump may refer to the solder material itself, either in its pre- or post-reflow state. A solder “joint” may generally refer to a post-reflow construct that includes a solder ball coupled with two substrates, as described in further detail below.

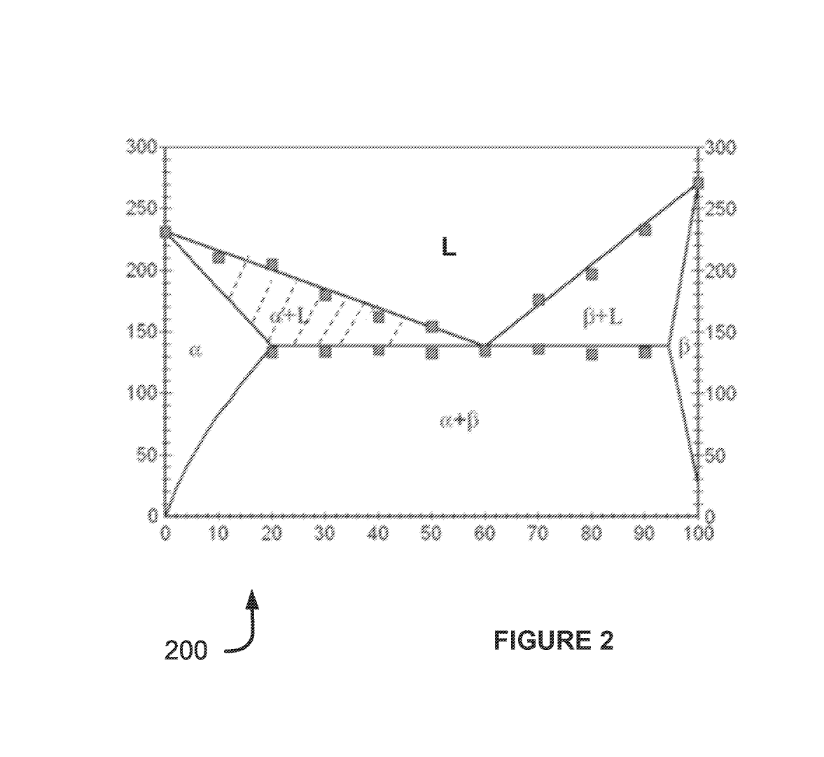

FIG. 2 depicts an example phase diagram 200 of an off-eutectic solder material such as a Sn—Bi solder. The x axis may show the percentage of bismuth in the Sn—Bi solder material. The y axis may show the temperature in degrees Celsius. The portions designated with α and β may indicate portions of the phase diagram where the different elements are present in solid form, while the portions designated with an L may indicate areas where portions of the solder may be liquid.

Specifically, if the element tin is associated with a, and the element bismuth is associated with β, then the region designated with only a may indicate a region of the phase diagram where tin is in solid phase, and the region designated with only β may indicate a region of the phase diagram where bismuth is in solid phase. The region designated by α+β may indicate a region of the phase diagram where the solder material includes both solid tin and solid bismuth. The region designated by L may indicate a region of the phase diagram where both the tin and bismuth are liquid. The eutectic composition in the phase diagram may be the point where an α+β system completely transitions into L. The regions α+L and β+L may be two phase solid+liquid regions that occur between α+β and L phases when a non-eutectic composition is heated. In the α+L phase at 140° C., the solder may include 20% tin in a phase and 42% tin in L phase because of different miscibility of bismuth in solid tin versus liquid tin. Similarly in the β+L at 140° C., the solder may include approximately 95% bismuth in β phase and 58% bismuth in L phase because of different miscibility of tin in solid bismuth versus liquid bismuth.

The region designated by α+L may indicate a region in the phase diagram where the solder includes solid tin (as designated by the a) as well as molten solder (as designated by the L). Similarly, the region designated by β+L may indicate a region of the phase diagram where the solder includes solid bismuth (as designated by the β) as well as molten solder (as designated by the L.) Generally, the diagonal lines above the α+L region and β-L region may be considered to be the liquidus temperatures for the different solder formulations, while the generally horizontal line at approximately 140° C. may be considered to be the solidus temperature for the different solder formulations. The space between the diagonal lines above the α+L region and β-L region and the generally horizontal line may be considered to be a region between the solidus and the liquidus temperatures for the different alloy formations.

In legacy packages, reflow during surface mount processes may have been accomplished at temperatures greater than the liquidus temperature of the solder. In such a process, the legacy solder may have been completely molten, and therefore exhibited a liquid-like behavior. This molten solder may have been deformed by compressive stresses from package dynamic warpage during reflow, and the deformed solder may have bridged with another solder bump or solder ball. As used herein, “bridging” may refer to the process where a molten solder ball becomes so deformed by compressive stresses that the resultant joint occupies a large lateral area and physically and electrically couples with an adjacent solder joint.

However, in embodiments herein if the solder is heated to a temperature that is less than the liquidus temperature of the off-eutectic solder material, then a portion of the mass of the solder may become molten while the remainder of the mass is still a solid. At this temperature, the solder may not collapse.

As an example of embodiments herein, the solder may be heated to a temperature that is between the solidus temperature and the liquidus temperature (i.e., in the α-L region or β-L region of the phase diagram of FIG. 2) and the solder joint may be formed. As used herein, a solder joint may be referred to as a solder connection between a BGA such as BGA 100 and a substrate as explained in further detail below.

As a specific example, for a given formulation of an SN—Bi solder, assume that the solidus temperature of the solder is approximately 140° C., and the liquidus temperature of the solder is approximately 175° C. In some embodiments, the solidus and/or liquidus temperatures may vary and be, for example, between approximately 135° C. and approximately 145° C. or between approximately 170° C. or 180° C., respectively. However, for the sake of this example, a temperature of approximately 140° C. will be used to describe the solidus temperature and a temperature of approximately 175° C. will be used to describe the liquidus temperature. As the solder is heated to the solidus temperature of 140° C., approximately half of the mass of the solder ball may become molten. However, the solder ball may not collapse at this temperature range. However, with continued heating beyond the solidus temperature of approximately 140° C., an increased amount of the mass of the solder may continue to transition to a molten state, and the solder ball may eventually collapse under its own weight. This collapse may occur at a temperature below the liquidus temperature of approximately 175° C., for example, in the temperature range of approximately 150° C.-160° C.

The temperature range of approximately 150° C.-160° C. may be a desirable temperature range at which to make a solder joint, because the solder may be sufficiently liquid to collapse and make a joint, while still remaining sufficiently solid to provide resistance to stresses from package dynamic warpage. Outside of the temperature range of approximately 150° C.-160° C., the molten phase of the solder may continue to increase until the liquidus temperature is reached. At this point, the bridging risk of the solder may be significantly higher beyond liquidus because the solder may be completely molten (i.e., liquid) and there may be no solid phase left to resist the collapse of the solder ball.

It will be understood that the above described temperature ranges are intended as one example of an off-eutectic solder material, and in other embodiments different temperature ranges may be desirable dependent on the type of solder alloy used, the type or amount of dopant, the different ratios of elements within the alloy itself, the size or width of the various solder balls, the desired properties of the solder joint, the solidus and/or liquidus temperatures of the off-eutectic solder material, and/or one or more additional or alternative parameters.

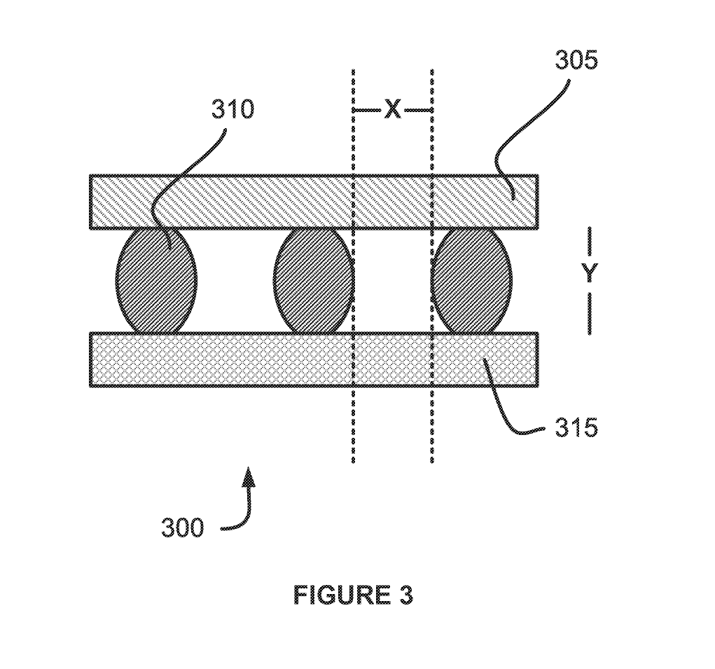

FIG. 3 depicts an example of a package 300 that may include a plurality of solder joints. Specifically, a BGA such as BGA 100 may include a substrate 305 and a plurality of solder balls 310 that may be similar to substrate 105 and solder balls 110 and 115. In embodiments, the solder balls 310 and/or package 300 may have been heated during a reflow process to a temperature between a solidus temperature and a liquidus of the solder balls 310, as described above. For example, if the solder balls 310 were composed of the off-eutectic material described above with a solidus temperature of approximately 140° C. and a liquidus temperature of approximately 175° C., then the solder balls 310 and/or package 300 may have been heated to a temperature between approximately 150° C. and 160° C. In embodiments, this heating may have occurred during a reflow process or during some other process. Once heated, the solder balls 310 may have been placed against a second substrate 315 and allowed to cool, thereby forming one or more joints. In embodiments, the substrate 315 may be composed of a material similar to that of substrate 105 as described above. In some embodiments, one or both of substrates 305 and/or 315 may have one or more pads, traces, and/or vias that may carry electrical signals to or from the solder balls 310 such that signals can be passed from substrate 305 to substrate 315, or vice versa, via solder balls 310.

Embodiments of the present disclosure may present significant advantages over legacy systems. Specifically, because lateral compression-based deformation of the solder balls 310 may be limited, the solder balls 310 may be placed closer to one another than was previously accomplished in legacy packages, thereby providing a greater signal density. For example, in previous packages, the solder balls may have had an X-distance (as indicated by the dashed lines and the designator “X” in FIG. 3) of approximately 0.6 micrometers (microns). However, in embodiments herein the X-distance between adjacent balls 310 may be less than approximately 0.6 microns, and be on the order of approximately 0.5 microns. Additionally, in some embodiments the solder joints may have a height (designated by the solid lines and the designator “Y” in FIG. 3, also referred to as a Z-height in some embodiments) that is greater than or equal to a height of the solder ball 310 prior to the reflow process. The joint may have this distance Y because the collapsed solder may elongate or stretch out due to dynamic warpage of the package during the reflow process.

Additionally, in legacy reflow processes, the interior solder balls 115 and the exterior solder balls 110 may have formed joints with varying “Y” heights. However, in embodiments herein the “Y” distance of joints formed from interior solder balls 115 may be approximately equal to, or within approximately 30% of the “Y” height of joints formed from exterior solder balls 110.

In some embodiments, the substrate 305 may be, for example, a substrate of a client processor, a server processor, a dynamic random access memory (DRAM), a package on package (PoP), or some other type of BGA package. In embodiments, the substrate 315 may be a substrate of, for example, a printed circuit board (PCT) like a motherboard, an interposer, or some other type of package.

In some embodiments, the solder joints that include the solder balls 310 may include a joint reinforcing paste (JRP), not shown in FIG. 3 for the sake of clarity. In embodiments, the JRP may be a relatively low-temperature solder paste. For example, the JRP may have a reflow or melting point of approximately 160 degrees Celsius, though in other embodiments the reflow point may be higher or lower dependent on parameters of the package 300 architecture and desired reflow-temperatures identified for construction of the package 300.

In some embodiments, the JRP may be similar to a no-clean type of solder paste. Specifically the JRP may, during the reflow process to form solder joints of the package 300, leave behind an electrically inert residue that does not contribute to structural weaknesses or bridging between the solder joints. In some embodiments, the JRP may be an epoxy-based paste. In some embodiments, the JRP may include an anhydrite and/or catalyst-based hardener. In some embodiments, the JRP may further include or be composed of solvents, organic acids, thixotropic agents/other rheology modifiers and anti-foaming agents.

In embodiments, during reflow the JRP may at least partially melt and flow around one or more of the solder balls 310. Subsequent to the reflow process, the JRP, and particularly the residue in the JRP, may harden and at least partially surround one or more of the solder balls 310, providing structural support for the solder joints that include the solder balls 310. In this manner, the structural support for the package 300 in general and the solder joints in specific may come from the JRP, thereby negating the need for an underfill material between the substrates 305 and 315.

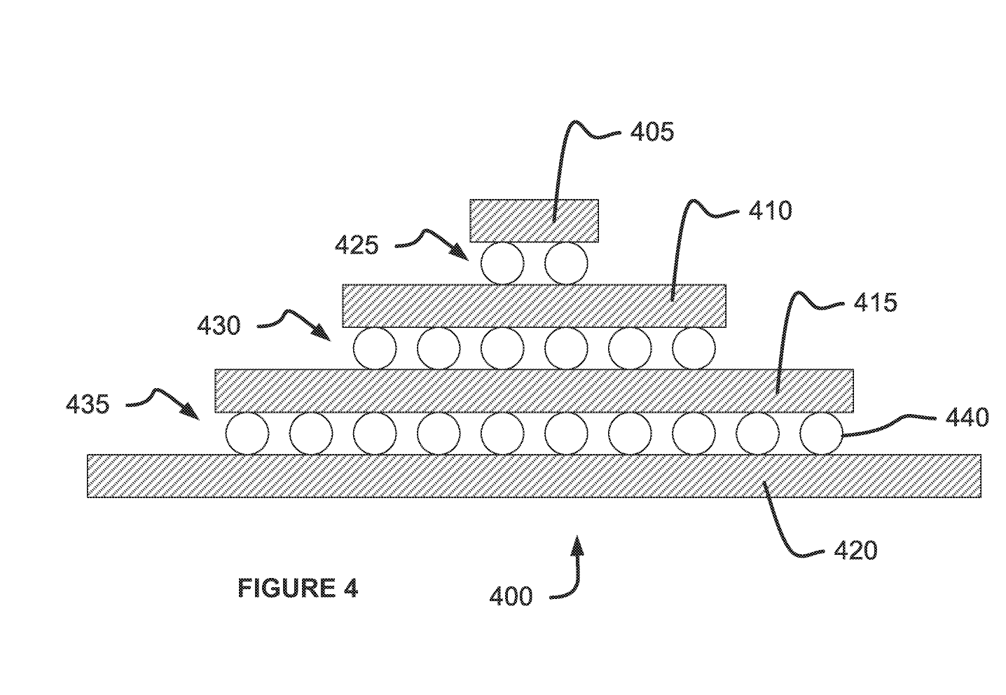

FIG. 4 depicts an example of an integrated circuit (IC) package 400 that may include one or more BGA packages such as BGA package 100. Specifically, the IC package 400 may include a die 405, a patch 410, an interposer 415, and/or a motherboard 420. In embodiments, the die 405 may be coupled with the patch 410 via one or more solder joints 425. In this embodiment, the die 405 may be considered to be the substrate 305 and the patch 410 may be considered to be the substrate 315. Additionally or alternatively, the patch 410 may be coupled with the interposer 415 via one or more solder joints 430. In this embodiment, the patch 410 may be considered to be the substrate 305 and the interposer 415 may be considered to be the substrate 315.

Additionally or alternatively, the interposer 415 may be coupled with the motherboard 420 via one or more solder joints 435. In this embodiment, the interposer 415 may be considered to be the substrate 305 and the motherboard 420 may be considered to be the substrate 315. In embodiments, the joints 425, 430, and 435 may include one or more solder balls 440 that may be similar to solder ball 310. In some embodiments, the solder joints 425 may be referred to as a first level interconnect (FLI). In some embodiments the solder joints 430 may be referred to as a mid level interconnect (MLI). In some embodiments, the solder joints 435 may be referred to as a second level interconnect (SLI).

It will be recognized that the relative sizes of the die 405, patch 410, interposer 415, and motherboard 420 are intended merely as illustrative examples in FIG. 4, and in other boards the size of the various elements may be different. Additionally, in some embodiments certain elements such as the patch 410 and/or interposer 415 may not be present. In some embodiments, the number of solder balls in the solder joints 425, 430, and/or 435 may be different than what is illustrated in FIG. 4.

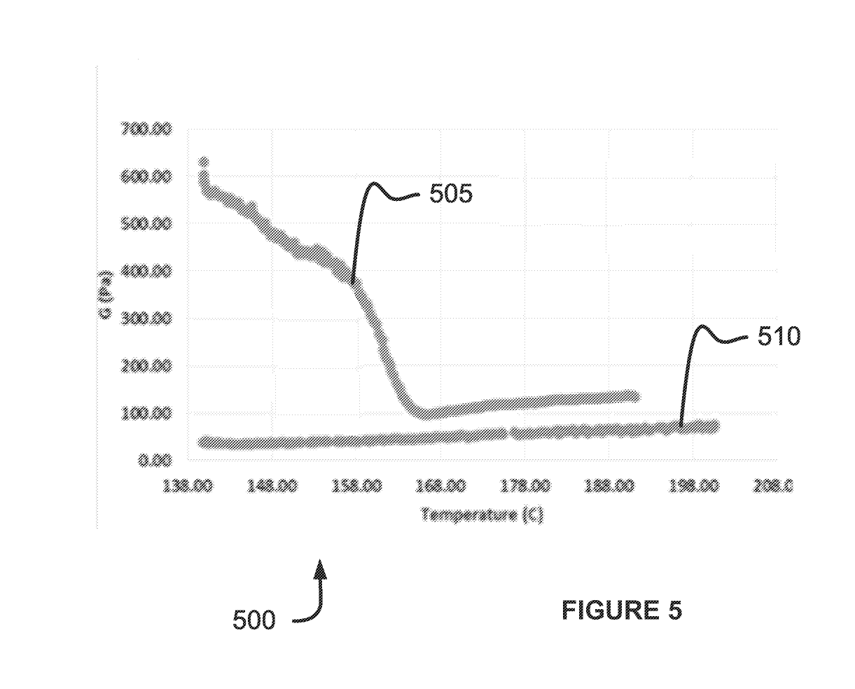

FIG. 5 depicts an example 500 of shear modulus of an off-eutectic solder (represented by line 505) and a legacy eutectic solder (represented by line 510). Specifically, the off-eutectic solder may have a solidus temperature of approximately 140° C. and a liquidus temperature of approximately 175° C. The x axis of FIG. 5 may depict reflow temperature in ° C., and the y axis of FIG. 5 may depict the shear modulus measured in Pascals (Pa). As can be seen, at a reflow temperature of approximately 160° C., the shear modulus of the line 505 related to off-eutectic solder may be approximately 10× that of the line 510 related to the legacy eutectic solder 510.

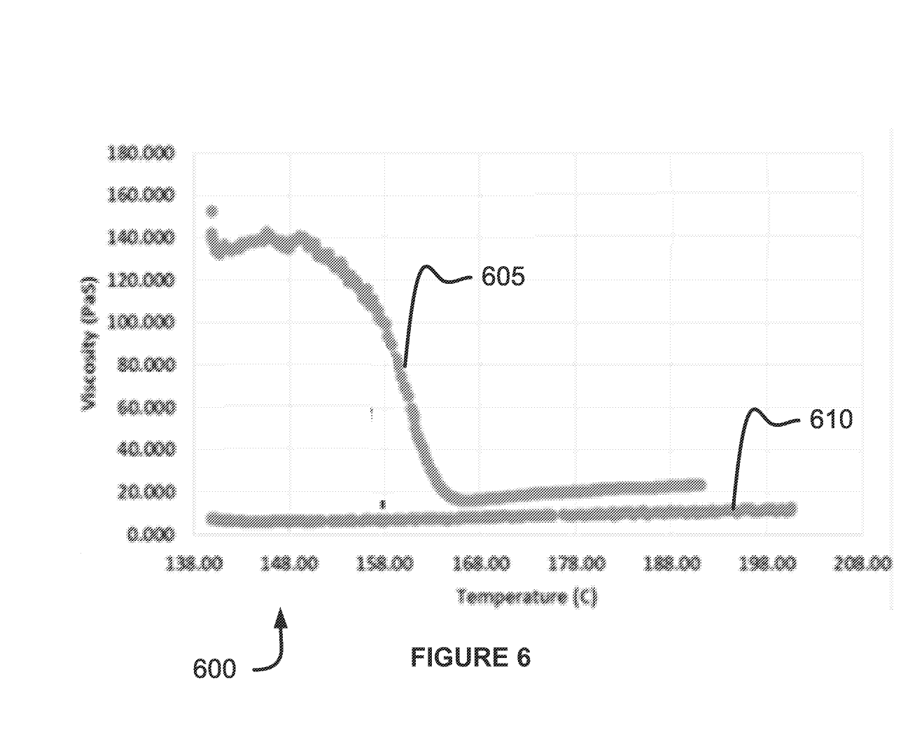

Similarly, FIG. 6 depicts an example 600 of viscosity of an off-eutectic solder (represented by line 605) and a legacy eutectic solder (represented by line 610). The off-eutectic solder may have a solidus temperature of approximately 140° C. and a liquidus temperature of approximately 175° C. The x axis of FIG. 6 may depict reflow temperature in ° C., and the y axis of FIG. 6 may depict viscosity in Pascals per Second (PaS). As can be seen, at a reflow temperature of approximately 160° C., the viscosity of the off-eutectic solder as represented by line 605, may be approximately 10x that of the legacy eutectic solder, as represented by line 610.

This significantly increased shear modulus and viscosity may reduce the structural deformation of off-eutectic solder balls during a reflow process at a temperature between the solidus and liquidus temperatures of the off-eutectic solder. The reduced structural deformation may reduce bridging between solder balls of the BGA 100, the package 300, and/or the IC package 400.

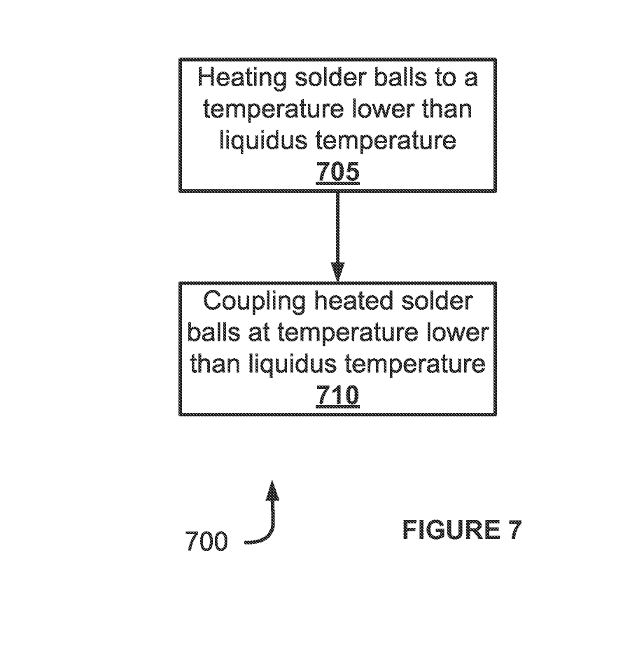

FIG. 7 depicts an example process 700 for constructing a package such as package 300.

In embodiments, the process 700 may include heating a plurality of solder balls of an off-eutectic solder material to a temperature lower than liquidus temperature of the off-eutectic solder material at 705. The solder balls may be solder balls of a BGA package such as BGA package 100. For example, in some embodiments the solder balls may be similar to solder balls 110, 115, or 310, and the BGA package may include a substrate such as substrate 105 or 305. Specifically, if the liquidus temperature of the off-eutectic solder material is, for example, approximately 175° C., then the process may include heating the off-eutectic solder material to a temperature of between approximately 150° C. and 160° C. This heating may occur, for example, during a reflow process.

The process 700 may further include coupling, while the off-eutectic solder material is at the temperature lower than the liquidus temperature of the off-eutectic solder material, the solder balls to a substrate at 710. The coupling may result in forming a plurality of solder joints between the BGA package and a substrate such as substrate 315.

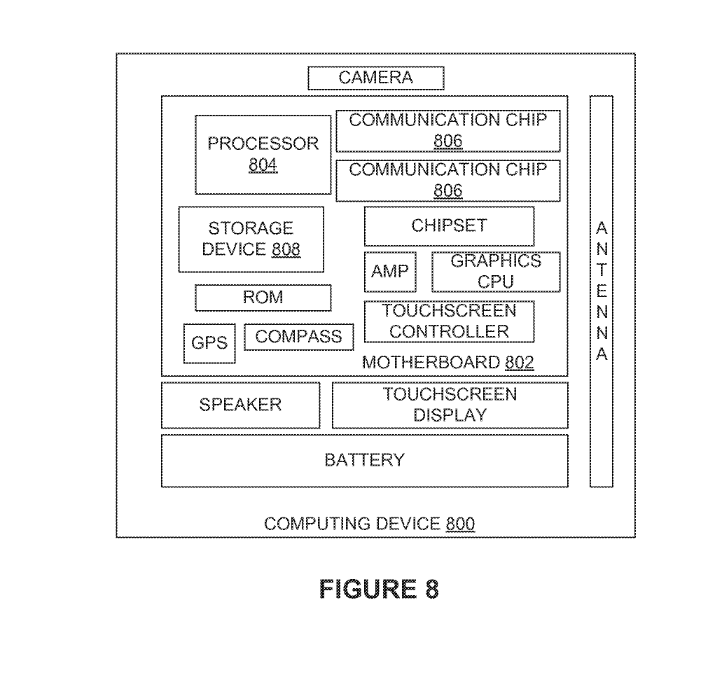

Embodiments of the present disclosure may be implemented into a system using any interposers, IC packages, or IC package structures that may benefit from the off-eutectic solder material and manufacturing techniques disclosed herein. FIG. 8 schematically illustrates a computing device 800, in accordance with some implementations, which may include one or more BGAs such as BGA 100, packages such as package 300, and/or IC packages such as IC package 400. For example, the substrates 105 and/or 305, or the die 405 may include a storage device 808, a processor 804, and/or a communication chip 806 of the computing device 800 (discussed below).

The computing device 800 may be, for example, a mobile communication device or a desktop or rack-based computing device. The computing device 800 may house a board such as a motherboard 802. In embodiments, the motherboard 802 may be similar to substrate 315 and/or motherboard 420. The motherboard 802 may include a number of components, including (but not limited to) a processor 804 and at least one communication chip 806. Any of the components discussed herein with reference to the computing device 800 may be arranged in or coupled with a BGA such as BGA 100, or incorporated into package 300 or IC package 400 as discussed herein. In further implementations, the communication chip 806 may be part of the processor 804.

The computing device 800 may include a storage device 808. In some embodiments, the storage device 808 may include one or more solid state drives. Examples of storage devices that may be included in the storage device 808 include volatile memory (e.g., dynamic random access memory (DRAM)), non-volatile memory (e.g., read-only memory, ROM), flash memory, and mass storage devices (such as hard disk drives, compact discs (CDs), digital versatile discs (DVDs), and so forth).

Depending on its applications, the computing device 800 may include other components that may or may not be physically and electrically coupled to the motherboard 802. These other components may include, but are not limited to, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, and a camera.

The communication chip 806 and the antenna may enable wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible broadband wide region (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 806 may operate in accordance with a Global System for Mobile Communications (GSM), General Packet Radio Service (GPRS), Universal Mobile Telecommunications System (UMTS), High Speed Packet Access (HSPA), Evolved HSPA (E-HSPA), or LTE network. The communication chip 806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 806 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 806 may operate in accordance with other wireless protocols in other embodiments.

The computing device 800 may include a plurality of communication chips 806. For instance, a first communication chip 806 may be dedicated to shorter range wireless communications such as Wi-Fi and Bluetooth, and a second communication chip 806 may be dedicated to longer range wireless communications such as GPS, EDGE, GPRS, CDMA, WiMAX, LTE, EV-DO, and others. In some embodiments, the communication chip 806 may support wired communications. For example, the computing device 800 may include one or more wired servers.

The processor 804 and/or the communication chip 806 of the computing device 800 may include one or more dies or other components in an IC package. Such an IC package may be coupled with an interposer or another package using any of the techniques disclosed herein. The term “processor” may refer to any device or portion of a device that processes electronic data from registers and/or memory to transform that electronic data into other electronic data that may be stored in registers and/or memory.

In various implementations, the computing device 800 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data. In some embodiments, the recessed conductive contacts disclosed herein may be implemented in a high-performance computing device.

The following paragraphs provide examples of various ones of the embodiments disclosed herein.

Example 1 may include an apparatus comprising: a first substrate; and a ball grid array (BGA) package that includes a second substrate soldered to the first substrate via a plurality of solder balls comprising an off-eutectic material such that respective solder balls of the plurality of solder balls form respective joints between the first substrate and the second substrate, wherein a first joint of the respective joints is less than 0.6 micrometers from a second joint of the respective joints.

Example 2 may include the apparatus of example 1, wherein the off-eutectic material includes tin (Sn) and bismuth (Bi).

Example 3 may include the apparatus of example 1, wherein the first joint is an interior joint and a third joint of the respective joints is an edge joint, and the first joint and third joint have an approximately equal height as measured from the first substrate to the second substrate.

Example 4 may include the apparatus of example 3, wherein the height of the first joint is greater than or equal to a height of one of the plurality of solder balls prior to a soldering process.

Example 5 may include the apparatus of any of examples 1-4, wherein the off-eutectic material has a solidus temperature and a liquidus temperature that is higher than the solidus temperature.

Example 6 may include the apparatus of example 5, wherein the solidus temperature is a temperature at which the off-eutectic material transitions from a liquid to a solid while cooling.

Example 7 may include the apparatus of example 6, wherein the solidus temperature is between approximately 135 degrees Celsius and approximately 145 degrees Celsius.

Example 8 may include the apparatus of example 5, wherein the liquidus temperature is a temperature at which the off-eutectic material transitions from a solid to a liquid while heating.

Example 9 may include the apparatus of example 8, wherein the liquidus temperature is between approximately 170 degrees Celsius and approximately 180 degrees Celsius.

Example 10 may include the apparatus of example 5, wherein the second substrate was soldered to the first substrate at a temperature between the solidus temperature and the liquidus temperature.

Example 11 may include the apparatus of any of examples 1-4, wherein the respective joints are middle level interconnect (MLI) joints or second level interconnect (SLI) joints.

Example 12 may include the apparatus of any of examples 1-4, wherein the respective joints include an epoxy-based joint reinforcing paste (JRP).

Example 13 may include a method comprising: heating a plurality of solder balls made of an off-eutectic material in a ball grid array (BGA) of a BGA package to a temperature lower than a liquidus temperature of the off-eutectic material; and coupling, while the off-eutectic material is at the temperature lower than the liquidus temperature, the solder balls to a substrate to form a plurality of solder joints between the BGA package and the substrate.

Example 14 may include the method of example 13, wherein the off-eutectic material further has a solidus temperature that is lower than the liquidus temperature, and the coupling is performed while the temperature of the off-eutectic material is higher than the solidus temperature.

Example 15 may include the method of example 14, wherein the solidus temperature is a temperature at which the off-eutectic material transitions from a liquid to a solid while cooling.

Example 16 may include the method of example 15, wherein the solidus temperature is between approximately 135 degrees Celsius and approximately 145 degrees Celsius.

Example 17 may include the method of example 14, wherein the liquidus temperature is a temperature at which the off-eutectic material transitions from a solid to a liquid while heating.

Example 18 may include the method of example 17, wherein the liquidus temperature is between approximately 170 degrees Celsius and approximately 180 degrees Celsius.

Example 19 may include the method of any of examples 13-18, wherein the off-eutectic material includes tin (Sn) and bismuth (Bi).

Example 20 may include the method of any of examples 13-18, wherein a first joint in the plurality of solder joints is approximately 0.5 micrometers from a second joint in the plurality of solder joints.

1. An apparatus comprising:
a first substrate; and
a ball grid array (BGA) package that includes a second substrate soldered to the first substrate via a plurality of solder balls comprising an off-eutectic material such that respective solder balls of the plurality of solder balls form respective joints between the first substrate and the second substrate, wherein a first joint of the respective joints is less than 0.6 micrometers from a second joint of the respective joints.

2. The apparatus of claim 1, wherein the off-eutectic material includes tin (Sn) and bismuth (Bi).

3. The apparatus of claim 1, wherein the first joint is an interior joint and a third joint of the respective joints is an edge joint, and the first joint and third joint have an approximately equal height as measured from the first substrate to the second substrate.

4. The apparatus of claim 3, wherein the height of the first joint is greater than or equal to a height of one of the plurality of solder balls prior to a soldering process.

5. The apparatus of claim 1, wherein the off-eutectic material has a solidus temperature and a liquidus temperature that is higher than the solidus temperature.

6. The apparatus of claim 5, wherein the solidus temperature is a temperature at which the off-eutectic material transitions from a liquid to a solid while cooling.

7. The apparatus of claim 6, wherein the solidus temperature is between approximately 135 degrees Celsius and approximately 145 degrees Celsius.

8. The apparatus of claim 5, wherein the liquidus temperature is a temperature at which the off-eutectic material transitions from a solid to a liquid while heating.

9. The apparatus of claim 8, wherein the liquidus temperature is between approximately 170 degrees Celsius and approximately 180 degrees Celsius.

10. The apparatus of claim 5, wherein the second substrate was soldered to the first substrate at a temperature between the solidus temperature and the liquidus temperature.

11. The apparatus of claim 1, wherein the respective joints are middle level interconnect (MLI) joints or second level interconnect (SLI) joints.

12. The apparatus of claim 1, wherein the respective joints include an epoxy-based joint reinforcing paste (JRP).

13. A method comprising:
heating a plurality of solder balls made of an off-eutectic material in a ball grid array (BGA) of a BGA package to a temperature lower than a liquidus temperature of the off-eutectic material; and
coupling, while the off-eutectic material is at the temperature lower than the liquidus temperature, the solder balls to a substrate to form a plurality of solder joints between the BGA package and the substrate.

14. The method of claim 13, wherein the off-eutectic material further has a solidus temperature that is lower than the liquidus temperature, and the coupling is performed while the temperature of the off-eutectic material is higher than the solidus temperature.

15. The method of claim 14, wherein the solidus temperature is a temperature at which the off-eutectic material transitions from a liquid to a solid while cooling.

16. The method of claim 15, wherein the solidus temperature is between approximately 135 degrees Celsius and approximately 145 degrees Celsius.

17. The method of claim 14, wherein the liquidus temperature is a temperature at which the off-eutectic material transitions from a solid to a liquid while heating.

18. The method of claim 17, wherein the liquidus temperature is between approximately 170 degrees Celsius and approximately 180 degrees Celsius.

19. The method of claim 13, wherein the off-eutectic material includes tin (Sn) and bismuth (Bi).

20. The method of claim 13, wherein a first joint in the plurality of solder joints is approximately 0.5 micrometers from a second joint in the plurality of solder joints.
